(19) United States
(12) Patent Application Publication
(10) Pub. No.: US 2026/0136575 A1
(43) Pub. Date: May 14, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Jung-Hung CHANG, Hsinchu (TW); Shih-Cheng CHEN, Hsinchu (TW); Tsung-Han CHUANG, Hsinchu (TW); Fu-Cheng CHANG, Hsinchu (TW); Wen-Ting LAN, Hsinchu (TW); Kuo-Cheng CHIANG, Hsinchu (TW)

(73) Assignee: Taiwan Semiconductor Manufacturing Company, Ltd., Hsinchu (TW)

(21) Appl. No.: 18/941,494

(22) Filed: Nov. 8, 2024

(51) Int. Cl. H01L 29/66; H01L 29/06; H01L 29/08; H01L 29/423; H01L 29/775; H01L 29/786

(52) U.S. Cl. CPC H10D 30/014; H10D 30/43; H10D 30/6735; H10D 30/6757; H10D 62/121; H10D 62/151; H10D 64/017; H10D 64/018

(57) ABSTRACT

A method for manufacturing a semiconductor device includes following steps. A sacrificial dielectric layer is formed between a plurality of first semiconductor layers and in a source/drain region. Edge portions and bottom portions of the sacrificial dielectric layer are removed. Dielectric spacers are formed on sidewalls of the sacrificial dielectric layer and between the first semiconductor layers. A substrate surface at the bottom of the source/drain region is etched to form a trench, wherein the trench is formed after forming the dielectric spacers, and the depth of the trench is less than the width of the trench.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14 illustrate B-B′ cross-sectional perspective views of various stages for manufacturing the semiconductor device in the Y-Z direction of FIG. 19 according to embodiments of the present disclosure.

FIGS. 15 and 16 respectively illustrate B-B′ cross-sectional and C-C′ cross-sectional schematic diagrams of a semiconductor device in the X-Z direction and Y-Z direction of FIG. 19 according to an embodiment of the present disclosure.

FIGS. 17 and 18 respectively illustrate B-B′ cross-sectional and C-C′ cross-sectional schematic diagrams of a semiconductor device in the X-Z direction and Y-Z direction of FIG. 19 according to an embodiment of the present disclosure.

FIG. 19 illustrates an example of nano-FETs in a three-dimensional view in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure can pattern a gate all around (GAA) transistor structure by any suitable method. For example, one or more photolithography processes may be used to pattern the structure, including dual patterning processes or multiple patterning processes. Typically, a dual or multi-patterning process combines a photolithography process with a self-aligned process, allowing the creation of patterns with, for example, smaller pitches than achievable using a single direct photolithography process. For example, in one embodiment, a shallow source/drain trench is formed in the substrate after the dielectric inner spacers are formed to prevent dielectric film residue at the bottom during formation of the dielectric inner spacers and epitaxial source/drain features.

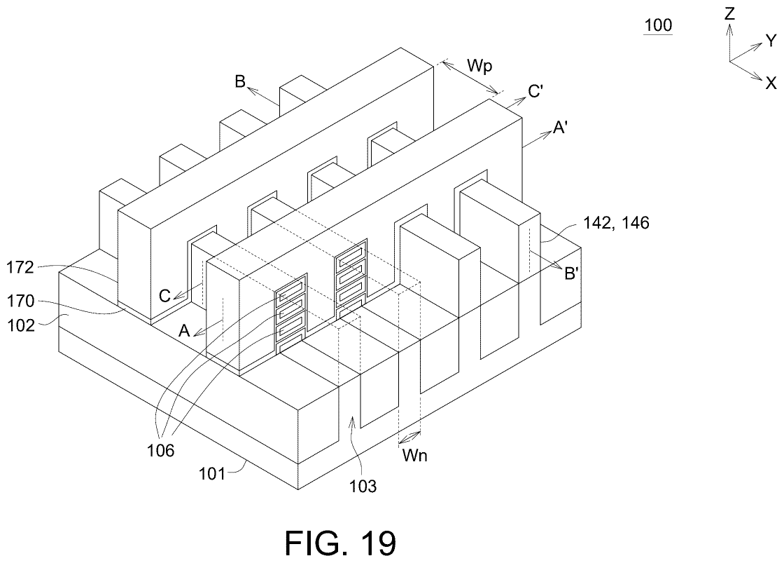

The present disclosure relates to semiconductor devices and methods of manufacturing the same. More specifically, some embodiments of the present disclosure relate to semiconductor devices including improved shallow source/drain trench for smaller contact poly pitch (CPP) Wp and smaller Y-cut nanosheet width Wn (refer to FIG. 19 and explanation below). The semiconductor devices proposed herein include p-type semiconductor devices or n-type semiconductor devices. Additionally, a semiconductor device may have one or more channel regions (e.g., nanowires) associated with a single continuous gate structure, or multiple gate structures. A person having ordinary skills may recognize other examples of semiconductor devices that may benefit from aspects of the present disclosure.

While the embodiments of this disclosure are discussed with respect to nanostructure channel FETs (e.g., Horizontal Gate All Around (HGAA) FETs, Vertical Gate All Around (VGAA) FETs, nanosheet/nanowire FET, nano-ribbon FET, Multi-Bridge-Channel FET), implementations of some aspects of the present disclosure may be used in other processes and/or in other devices, such as planar FETs, Fin-FETs, and other suitable devices. A person having ordinary skills in the art will readily understand other modifications that may be made are contemplated within the scope of this disclosure.

FIG. 19 illustrates an example of nano-FETs (e.g., nanowire FETs, nanosheet FETs, nanostructure FETs, or the like) in a three-dimensional view, in accordance with some embodiments. The nano-FETs comprise nanostructures 106 (e.g., nanosheets, nanowire, or the like) over fins 103 on a substrate 101 (e.g., a semiconductor substrate), wherein the nanostructures 106 act as channel regions for the nano-FETs. The nanostructure 106 may include p-type nanostructures, n-type nanostructures, or a combination thereof. Isolation regions 102 are disposed between adjacent fins 103, which may protrude above and from between neighboring isolation regions 102. Although the isolation regions 102 are described/illustrated as being separate from the substrate 101, as used herein, the term “substrate” may refer to the semiconductor substrate alone or a combination of the semiconductor substrate and the isolation regions. Additionally, although a bottom portion of the fins 103 are illustrated as being single, continuous materials with the substrate 101, the bottom portion of the fins 103 and/or the substrate 101 may comprise a single material or a plurality of materials. In this context, the fins 103 refer to the portion extending between the neighboring isolation regions 102.

Gate dielectric layers 170 are disposed over top surfaces of the fins 103 and along top surfaces, sidewalls, and bottom surfaces of the nanostructures 106. Gate electrode layers 172 are over the gate dielectric layers 170. Epitaxial source/drain features 142 and 146 are disposed on the fins 103 on opposing sides of each of the gate dielectric layers 170 and the gate electrode layers 172.

FIG. 19 further illustrates reference cross-sections that are used in later figures of the semiconductor device 100. Cross-section A-A′ is along a longitudinal axis of a gate electrode layer 102 and in a direction, for example, perpendicular to the direction of current flow between the epitaxial source/drain features 142 and 146 of a nano-FET. Cross-section B-B′ is perpendicular to cross-section A-A′ and is parallel to a longitudinal axis of a fin 103 of the nano-FET and in a direction of, for example, a current flow between the epitaxial source/drain features 142 and 146 of the nano-FET. Cross-section C-C′ is parallel to cross-section A-A′ and extends through the epitaxial source/drain features 142 and 146 of the nano-FETs. Subsequent figures refer to these reference cross-sections for clarity. Referring to FIG. 19, the contact poly pitch (CPP) Wp refers to the distance between two adjacent gate electrode layers 172 in the X direction, and the Y-cut nanosheet width Wn refers to the width of the first semiconductor layers 106 in the Y direction, i.e., the width of channel regions in the GAA transistors.

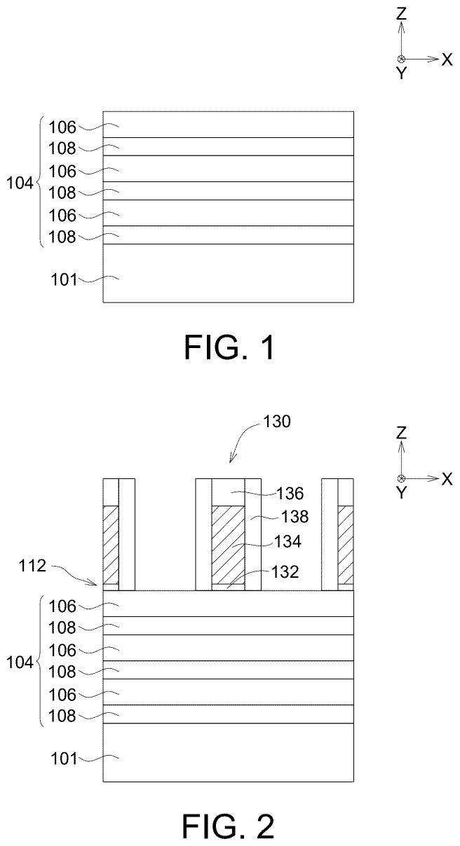

FIGS. 1-14 are perspective views of various stages for manufacturing a semiconductor device 100 according to embodiments of the present disclosure. It will be appreciated that for additional embodiments of the method, additional steps may be provided before, during, and after the processes illustrated in FIGS. 1-14, and some of the steps described below may be replaced or eliminated. The sequence of steps/processes is unrestricted and interchangeable.

As shown in FIG. 1, semiconductor device 100 includes a stack of semiconductor layers 104 formed over a substrate 101. The substrate 101 may be a semiconductor substrate. The substrate 101 may include single crystal semiconductor materials such as, but not limited to, silicon (Si), germanium (Ge), silicon germanium (SiGe), gallium arsenide (GaAs), indium antimonide (InSb), gallium phosphide (GaP), Gallium antimonide (GaSb), indium aluminum arsenide (InAlAs), indium gallium arsenide (InGaAs), gallium antimony phosphide (GaSbP), gallium arsenide antimonide (GaAsSb) and indium phosphide (InP). In some embodiments, the substrate 101 is a silicon-on-insulator (SOI) substrate having an insulating layer (not shown) disposed between two silicon layers for reinforcement. In one aspect, the insulating layer is an oxygen-containing layer.

The stack of semiconductor layers 104 includes semiconductor layers made of different materials to facilitate the formation of nanostructured channels in multi-gate devices such as nanostructured field effect transistors. In some embodiments, the stack of semiconductor layers 104 includes a plurality of first semiconductor layers 106 (i.e., nanosheet structures 106) and a plurality of second semiconductor layers 108 (also referred to as dummy layers). In some embodiments, the stack of semiconductor layers 104 includes alternating first semiconductor layers 106 and second semiconductor layers 108, and the first semiconductor layers 106 and the second semiconductor layers 108 are disposed parallel to each other. The first semiconductor layer 106 and the second semiconductor layer 108 are made of semiconductor materials with different etching selectivities and/or different oxidation rates. For example, the first semiconductor layer 106 can be made of Si, and the second semiconductor layer 108 can be made of SiGe. In some examples, first semiconductor layer 106 may be made of germanium-doped silicon, and second semiconductor layer 108 may be made of SiGe. In some examples, first semiconductor layer 106 can be made of SiGe and second semiconductor layer 108 can be made of Si. In some embodiments, the first semiconductor layer 106 can be made of SiGe having a first germanium concentration range, and the second semiconductor layer 108 can be made of SiGe having a second germanium concentration range that is lower or greater than the first germanium concentration range. Alternatively, in some embodiments, any one of the first semiconductor layer 106 and the second semiconductor layer 108 may be or include other materials, such as Ge, SiC, GeAs, GaP, InP, InAs, InSb, GaAsP, AlInAs, AlGaAs, InGaAs, GaInP, GaInAsP or any combination thereof. In some embodiments, the second semiconductor layers 108 may be crystal-oxide, such as HfO₂, ZrO₂, ZnO₂, MgO, IGZO, Y₂O₃ and beta-SiN.

The thickness of the first semiconductor layer 106 and the second semiconductor layer 108 may vary depending on application and/or device performance considerations. In some embodiments, each of the first semiconductor layer 106 and the second semiconductor layer 108 has a thickness between about 5 nm and about 30 nm. In other embodiments, each of the first semiconductor layer 106 and the second semiconductor layer 108 has a thickness between about 10 nm and about 20 nm. In some embodiments, each of the first semiconductor layer 106 and the second semiconductor layer 108 has a thickness between about 6 nm and about 12 nm. Each second semiconductor layer 108 may have a thickness equal to, smaller than, or larger than that of the first semiconductor layer 106. The second semiconductor layer 108 may eventually be removed and used to define the vertical distance between adjacent channels of the semiconductor device structure 100.

The first semiconductor layer 106 or a portion thereof may form the nanostructured channels of the semiconductor device 100 in a later manufacturing stage. The term “nanostructure” is used herein to mean any portion of a material that has a nanometer or even micron dimension and has an elongated shape, regardless of the cross-sectional shape of the portion. Accordingly, this term refers to elongated material portions and bundled or rod-like material portions of circular and substantially circular cross-sections, including, for example, cylindrical or substantially rectangular cross-sections. The nanostructure channels of the semiconductor device 100 may be surrounded by gate electrodes. The Semiconductor device 100 may include nanostructured transistors. Nanostructured transistors can be called nanowire transistors, gate-all-around transistors, multi-bridge channel (MBC) transistors, or any transistor with a gate electrode surrounding a channel. The use of first semiconductor layer 106 to define one or more channels of semiconductor device 100 is discussed further below.

The first semiconductor layer 106 and the second semiconductor layer 108 are formed by any suitable deposition process, such as an epitaxial process. For example, the stack of semiconductor layers 104 may be epitaxially grown by a molecular beam epitaxy (MBE) process, a metalorganic chemical vapor deposition (MOCVD) process, and/or other suitable crystal growth process. Although the four first semiconductor layers 106 and the four second semiconductor layers 108 are alternately stacked as shown in FIG. 1, it should be understood that according to the predetermined number of nanostructure channels of each field effect transistor. A stack of the semiconductor layer 104 can be any number of first semiconductor layers 106 and second semiconductor layers 108. For example, the number of first semiconductor layers 106 (i.e., the number of channels) may be between 2 and 8.

In some embodiments, a hard mask layer (not shown) formed on the stack of semiconductor layers 104 is patterned using multiple patterning steps including photolithography and etching processes. The etching process may include dry etching, wet etching, reactive ion etching (RIE) and/or other suitable processes. The photolithography process may include forming a photoresist layer (not shown) over the hard mask layer, exposing the photoresist layer to the pattern, performing a post-exposure bake process, and developing the photoresist layer to form a masking element of the photoresist layer. In some embodiments, an electron beam (e-beam) lithography process may be used to pattern the photoresist layer to form the masking element. The etching process creates trenches in the unprotected areas through the hard mask layer, through the stack of semiconductor layers 104 and into the substrate 101, leaving a plurality of vertically extending fin structures. The groove extends along the X direction. The trenches may be etched using dry etching (e.g., RIE), wet etching, and/or combinations thereof.

In FIG. 2, one or more sacrificial gate structures 130 are formed above the vertically extending fin structure 112. The sacrificial gate structure 130 may be formed over a portion of the fin structure 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 can be formed by sequentially depositing a blanket layer of the sacrificial gate dielectric layer 132, the sacrificial gate electrode layer 134, and the mask layer 136, and then these layers are patterned into a sacrificial gate structure 130. The gate spacers 138 are then formed on the sidewalls of the sacrificial gate structure 130. For example, the gate spacers 138 may be formed by conformally depositing one or more layers of gate spacers 138 and anisotropically etching the one or more layers. Although one sacrificial gate structure 130 is shown in the figures, in some embodiments, two or more sacrificial gate structures 130 may be configured along the X direction.

The sacrificial gate dielectric layer 132 may include one or more layers of dielectric material, such as a silicon oxide-based material. The sacrificial gate electrode layer 134 may include silicon, such as polycrystalline silicon or amorphous silicon. The mask layer 136 may include more than one layer, such as an oxide layer and a nitride layer. The gate spacer 138 may be made of a dielectric material, such as silicon oxide, silicon nitride, silicon carbide, silicon oxynitride (SiON), silicon nitride carbide (SiCN), silicon oxycarbide (SiCO), silicon oxynitride oxide (SiOCN) and/or combinations thereof.

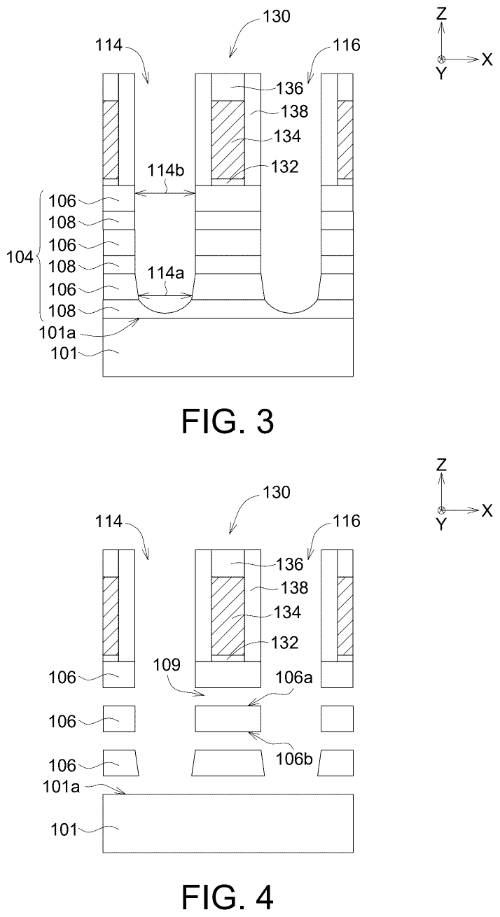

In FIG. 3, by removing the portion of the fin structure 112 that is not covered by the sacrificial gate structure 130, the two opposite sides of the first semiconductor layer 106 and the second semiconductor layer 108 are exposed. The first semiconductor layer 106 covered by the sacrificial gate electrode layer 134 of the sacrificial gate structure 130 serves as a channel region of the semiconductor device 100. Trenches that are exposed to opposite sides of the sacrificial gate structure 130 define source/drain (S/D) regions 114 and 116 of the semiconductor device 100. In some cases, some source/drain regions 114 and 116 may be shared between various transistors. For example, each of the source/drain regions 114 and 116 may be connected together and implemented as a multifunctional transistor. The trenches can be completed by an etching process, which can be dry etching or wet etching such as RIE, NBE or the like, such as using tetramethylammonium hydroxide (TMAH), ammonium hydroxide (NH₄OH) or any suitable etchant. In one embodiment, the source/drain regions 114 and 116 may have a taper shape on the bottom side whose X-cut width 114a is smaller than X-cut width 114b of the source/drain regions 114 and 116 on the top side. X-cut width refers to the width of the trench in the X direction along the extension of the fins 103 in FIG. 19.

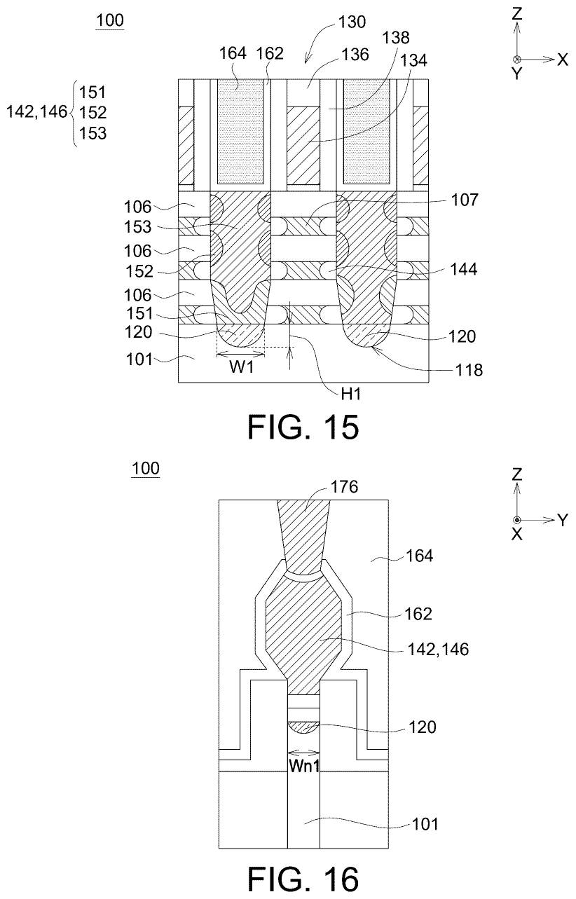

In FIG. 3, the trench depth of the source/drain regions 114 and 116 can be controlled by the etching process. In one embodiment, the bottom 115 of the trench is, for example, slightly higher than the upper surface 101a of the substrate 101 or coplanar with the upper surface 101a of the substrate 101. The etchant can reach the second semiconductor layer 108 at the lowest level through the trench, but does not penetrate the second semiconductor layer 108. Alternatively, in another embodiment, the etchant can reach the second semiconductor layer 108 at the lowest level through the trench, and penetrate the second semiconductor layer 108 completely to expose the upper surface 101a of the substrate 101. The above etching process is suitable for semiconductor devices with smaller contact poly pitch (CPP) and smaller Y-cut nanosheet width as shown in FIGS. 15 and 16. For example, the contact poly pitch (CPP) can be smaller than 40 nm and the Y-cut nanosheet width can be smaller than 12 nm.

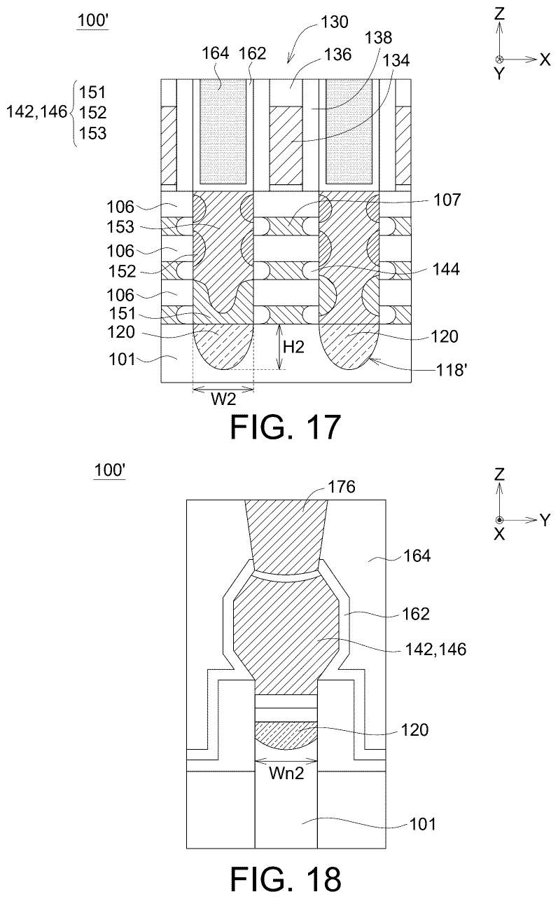

In some embodiments, if the etchant penetrates the second semiconductor layer 108 at the lowest level and etches the substrate 101 to form a deep trench at first, a semiconductor device 100′ with larger contact poly pitch (CPP) and lager Y-cut nanosheet width would be formed as shown in FIGS. 17 and 18. For example, the contact poly pitch (CPP) can be greater than 40 nm and the Y-cut nanosheet width can be greater than 12 nm.

Referring to FIG. 4, each second semiconductor layer 108 of the stack of semiconductor layers 104 is removed to form a cavity 109. In some embodiments, the second semiconductor layer 108 is removed through a wet etching process. In the case where the second semiconductor layer 108 is made of SiGe and the first semiconductor layer 106 is made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP) or potassium hydroxide (KOH) solutions to expose the upper and lower surfaces 106a and 106b of the first semiconductor layers 106 and the top surface 101a of the substrate 101.

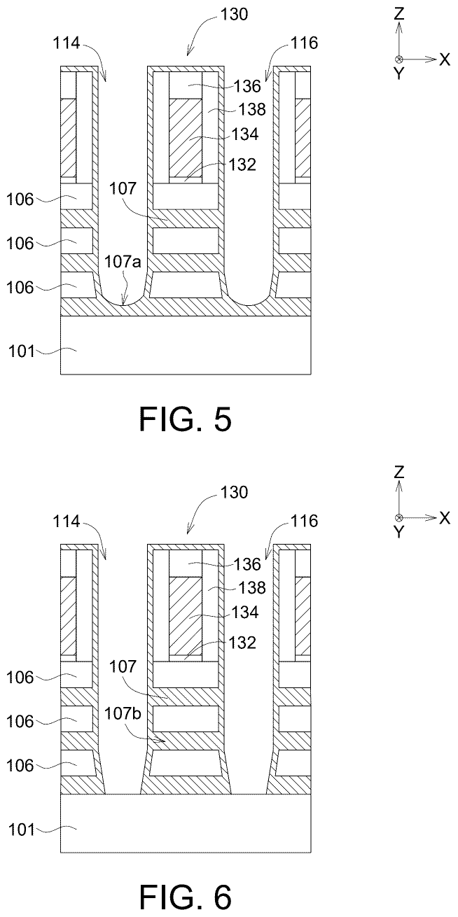

In FIG. 5, after the second semiconductor layer 108 is removed, a dielectric material is deposited on the upper and lower surfaces of the first semiconductor layer 106 and the upper surface 101a of the substrate 101 exposed in the cavity 141 to form a sacrificial dielectric layer 107. The sacrificial dielectric layer 107 may be made of a low-k dielectric material, such as SiOx. In addition, the sacrificial dielectric layer 107 may also cover the side surfaces of the sacrificial gate structure 130 and the side surfaces of each first semiconductor layers 106. The sacrificial dielectric layer 107 covers the upper surface 101a of the substrate 101, and the thickness of the bottom portion 107a of the sacrificial dielectric layer 107 is thinner (about less than 5 nm) to facilitate subsequent complete removal of the bottom portion 107a of the sacrificial dielectric layer 107.

In FIG. 6, selective etching is performed to remove the bottom portion 107a of the sacrificial dielectric layer 107 covering the upper surface 101a of the substrate 101, but leaving the portion of the sacrificial dielectric layer 107 at the side surfaces of the sacrificial gate structure 130 and the side surfaces of the first semiconductor layers 106. Selective etching may be dry or wet etching such as RIE, NBE or the like.

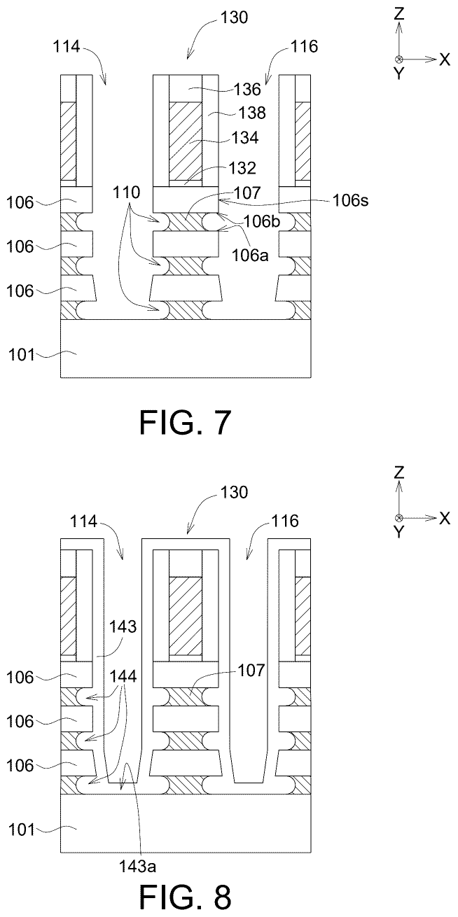

In FIG. 7, the edge portions 107b of the sacrificial dielectric layer 107 is removed horizontally along the X direction. In some embodiments, a portion of the sacrificial dielectric layer 107 is removed through a selective wet etching process. By removing the edge portion 107b of the sacrificial dielectric layer 107 along the X direction, the side surfaces 106s and a part of the upper and lower surfaces 106a and 106b of the first semiconductor layer 106 are exposed to form a cavity 110 between the first semiconductor layers 106.

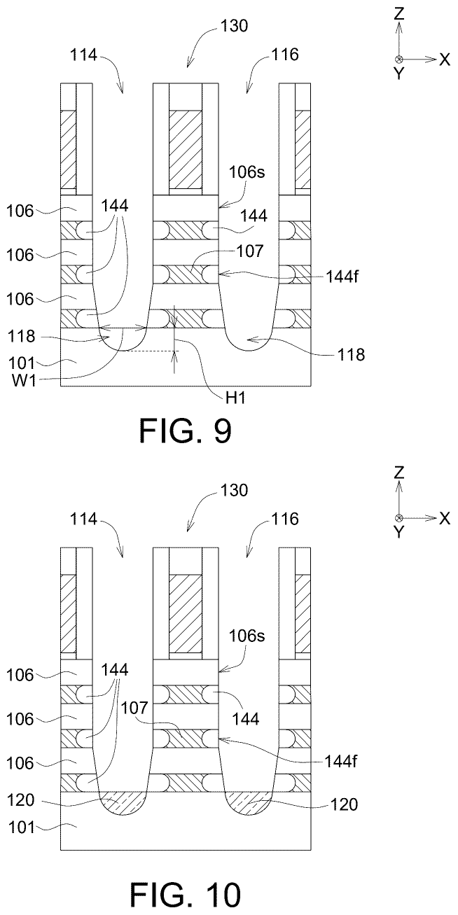

In FIG. 8, a dielectric layer 143 is deposited in each cavity 110 to form dielectric spacers 144 (or inner spacers). In addition to filling the cavity 110, the dielectric layer 143 is also deposited on the substrate 101 and the side surfaces of the first semiconductor layer 106. In FIG. 9, in order to avoid excess dielectric layer 143a remaining on the substrate 101, the dielectric layer 143 is partially removed through the etching process, leaving only the dielectric spacer 144 in the cavity 110. The etching process may be dry or wet etching such as RIE, NBE or the like. The dielectric spacers 144 may be made of a low-k dielectric material, such as SiON, SiCN, SiOC, SiOCN, or SiN. In some embodiments, the dielectric spacers 144 are formed from a material having a dielectric constant in the range of 3.5 to 5.5. The dielectric spacers 144 may be formed by atomic layer deposition, pulsed plasma chemical vapor deposition, or any suitable deposition process. The end portion of the dielectric spacers 144 below the first semiconductor layers 106 may have a flat surface 144f that is substantially coplanar with the side surface 106s of the first semiconductor layers 106.

In FIG. 9, a part of the substrate 101 located under the source/drain regions 114 and 116 is removed, for example, etched, to form at least two shallow trenches 118. The etching process may be dry etching such as RIE, NBE or the like, or wet etching, such as using tetramethylammonium hydroxide (TMAH), ammonium hydroxide (NH₄OH) or any suitable etchant to make the bottom portions of the source/drain regions 114 and 116 have shallow trenches 118. The depth H1 of the shallow trench 118 is about 5 to 10 nm, and the width W1 of the shallow trench 118 is about 10 to 15 nm. The depth H1 of shallow trench 118 is less than the width W1 of shallow trench 118. Since the depth H1 of the shallow trench 118 is small than 10 nm and the shallow trench 118 is formed after removing the dielectric layer 143 remaining on the top surface 101a of the substrate 101, there is no dielectric layer 143 attached to the substrate 101. The above-mentioned shallow trench process is suitable for a semiconductor device 100 with smaller Y-cut nanosheet width and smaller contact poly pitch (CPP) to prevent the depth of trenches from being too deep and leaving the dielectric layer in the trenches. For example, if a deep trench is formed at first in FIG. 3, the dielectric layer 143 would remain in the deep trench and the subsequent process cannot form a separation layer 120 at the bottom of the source/drain regions 114 and 116. In one embodiment, the separation layer 120 can be a layer formed by epitaxial deposition.

In FIG. 10, a semiconductor material (such as silicon germanium or silicon) can be further deposited or backfilled in the two shallow trenches 118 of the substrate 101 to form an separation layer 120. The top surface 120a of the separation layer 120 may be coplanar with or lower than the top surface 101a of the substrate 101. The separation layer 120 may be formed of an epitaxial growth single crystal semiconductor material, such as but not limited to silicon (Si), germanium (Ge), germanium tin (GeSn), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), antimonide arsenic gallium (GaAsSb), gallium nitride (GaN) and indium phosphide (InP). In one embodiment, the separation layer 120 includes a silicon germanium buffer layer epitaxially grown on the substrate 101. The germanium concentration of the silicon germanium buffer layer can be increased from 30 atomic percent germanium in the bottom buffer layer to 70 atomic percent germanium in the top buffer layer.

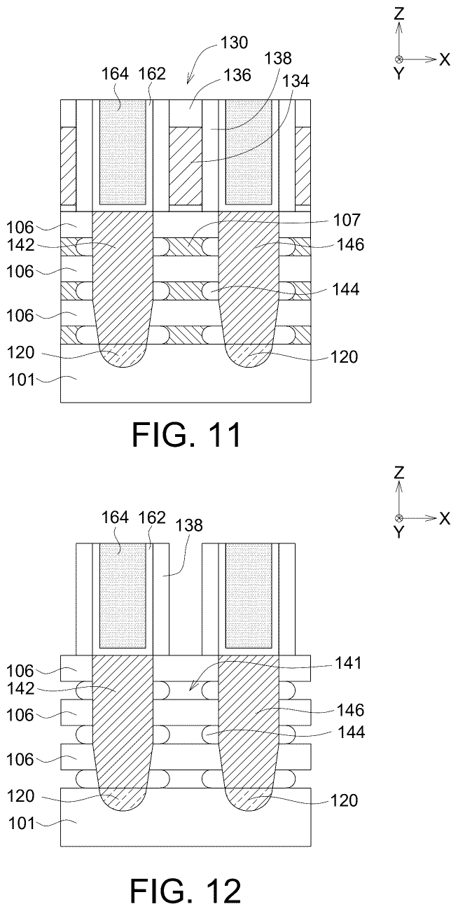

Referring to FIG. 11, in subsequent processes, epitaxial source/drain features 142 and 146 are formed in the source/drain regions 114 and 116. The epitaxial source/drain features 142 and 146 may be made of one or more layers of Si, SiP, SiC, and SiCP for n-channel FETs, or Si, SiGe, Ge for p-type channel FETs. For p-type channel FETs, p-type dopants such as boron may also be included in the epitaxial source/drain features 142 and 146. The epitaxial source/drain features 142 and 146 may be formed on the separation layer 120 by epitaxial growth methods using chemical vapor deposition, atomic layer deposition, or molecular beam epitaxy. The epitaxial source/drain features 142 and 146 may be grown vertically and horizontally to form facets, which may correspond to crystallographic planes of the material used for substrate 101. In some cases, the epitaxial source/drain features 142 and 146 may be grown and merged with adjacent epitaxial source/drain features 142 and 146. In some embodiments, prior to forming the epitaxial source/drain features 142 and 146, a source/drain pre-clean process may be performed to remove native oxide layers on the first semiconductor layers 106 and the dielectric spacers 144. The source/drain pre-cleaning process may be an inert gas sputtering process (e.g., argon sputtering) or a plasma-based cleaning process. In one embodiment, the source/drain pre-clean process is a SiCoNi process that uses remote plasma to generate ammonium fluoride (NH₄F) etchant from nitrogen trifluoride (NF₃) and ammonia (NH₃) to minimize damage to the semiconductor device 100.

In one example shown in FIG. 11, one of a pair of epitaxial source/drain features 142 and 146 disposed on one side of the sacrificial gate structure 130 is designated as the source feature (source terminal), and the other of the pair of epitaxial source/drain features 142 and 146 disposed on the other side of the sacrificial gate structure 130 is designated as the drain feature (the drain terminal). The source feature (source terminal) and the drain feature (drain terminal) are connected by a channel layer (e.g., first semiconductor layer 106). The epitaxial source/drain features 142 and 146 are in contact with the first semiconductor layer 106 beneath the sacrificial gate structure 130. In some cases, the epitaxial source/drain features 142 and 146 may grow beyond the topmost semiconductor channel (i.e., the first semiconductor layer 106) to contact the gate spacer 138.

In some embodiments, a contact etch stop layer (CESL) 162 is conformally formed on the exposed surface of the semiconductor device 100. The contact etch stop layer 162 covers the sidewalls of sacrificial gate structure 130 and the upper surfaces of epitaxial source/drain features 142 and 146. The contact etch stop layer 162 may include an oxygen-containing material or a nitrogen-containing material, such as silicon nitride, silicon carbonitride, silicon oxynitride, silicon carbonitride, silicon oxide, silicon oxycarbide, the like, or combinations thereof, and may be formed by CVD, PECVD, ALD or any suitable deposition technique. Next, a first interlayer dielectric (ILD) 164 is formed on the contact etch stop layer 162 of the semiconductor device 100. The material of the first interlayer dielectric layer 164 may include compounds including Si, O, C, and/or H, such as silicon oxide, ethyl orthosilicate oxide, SiCOH, and SiOC. Organic materials such as polymers may also be used for the first interlayer dielectric layer 164. The first interlayer dielectric layer 164 may be deposited by a PECVD process or other suitable deposition techniques. In some embodiments, after forming the first interlayer dielectric layer 164, the semiconductor device 100 may undergo a thermal process to anneal the first interlayer dielectric layer 164.

In FIG. 12, the sacrificial dielectric layer 107 between the first semiconductor layers 106 is removed to form a cavity 141. In some embodiments, the sacrificial dielectric layer 107 is removed through a selective wet etching process. The sacrificial dielectric layer 107 is removed to expose the upper and lower surfaces of the first semiconductor layer 106. In addition, plasma dry etching and/or wet etching may also be used to remove the sacrificial gate structure 130. The sacrificial gate electrode layer 134 may first be removed by any suitable process, such as dry etching, wet etching, or a combination thereof. The sacrificial gate dielectric layer 132 is then removed by performing any suitable process (such as dry etching, wet etching, or a combination thereof). In some embodiments, a wet etchant, such as a tetramethylammonium hydroxide solution, may be used to selectively remove the sacrificial gate electrode layer 134 but not the gate spacer 138, the first interlayer dielectric layer 164 and the contact etch stop layer 162.

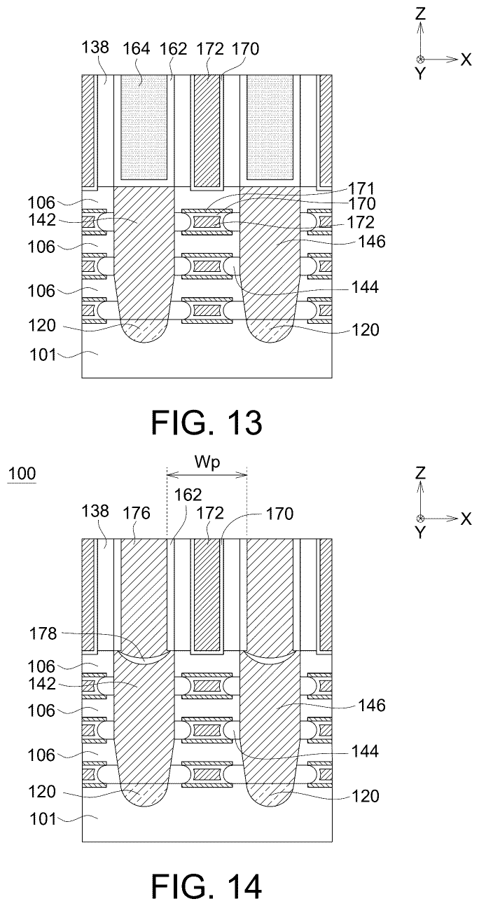

In FIG. 13, after the sacrificial dielectric layer 107 is removed, a gate dielectric layer 170 is formed to surround each of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interface layer (IL) 171 is formed between the gate dielectric layer 170 and the exposed surfaces of the first semiconductor layers 106. In such cases, the interface layer 171 may also be formed on the well portion of the substrate 101. The interface layer 171 may include or be made of oxygen-containing materials or silicon-containing materials, such as silicon oxide, silicon oxynitride, oxynitride, hafnium silicate, and the like. The interface layer 171 can be formed by CVD, ALD, cleaning process or any suitable process. In some embodiments, the gate dielectric layer 170 includes one or more layers of dielectric materials, such as silicon oxide, silicon nitride, high-k dielectric materials, other suitable dielectric materials, and/or combinations thereof. Examples of high-k dielectric materials include HfO₂, HfSiO, HfSiON, HfTaO, HfTiO, HfZrO, zirconium oxide, alumina, titanium oxide, hafnium dioxide-aluminum oxide (HfO₂—Al₂O₃) alloy, and other suitable high-k dielectric materials and/or combinations thereof. The gate dielectric layer 170 may be formed by CVD, ALD, or any suitable deposition technique.

The gate electrode layer 172 may include one or more layers of conductive materials, such as polycrystalline silicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials and/or any combination thereof. The gate electrode layer 172 may be formed by CVD, ALD, electroplating or other suitable deposition techniques. The gate electrode layer 172 may also be deposited over the upper surface of the first interlayer dielectric layer. Next, the gate dielectric layer 170 and the gate electrode layer 172 formed over the first interlayer dielectric layer 164 are removed by using, for example, chemical mechanical polishing until the top surface of the first interlayer dielectric layer 164 is exposed.

In FIG. 14, source/drain contacts 176 are formed in the first interlayer dielectric layer 164. Prior to forming the source/drain contacts 176, contact openings are formed in the first interlayer dielectric layer 164 to expose the epitaxial source/drain features 142 and 146. The contact openings are formed through various layers, including first interlayer dielectric layer 164 and contact etch stop layer 162, using suitable photolithography and etching techniques to expose epitaxial source/drain features 142 and 146. In some embodiments, upper portions of the epitaxial source/drain features 142 and 146 are etched.

After forming the contact openings, a silicide layer 178 is formed over the epitaxial source/drain features 142 and 146. The silicide layer 178 electrically couples epitaxial source/drain features 142 and 146 to subsequently formed source/drain contacts 176. The silicide layer 178 may be formed by depositing a metal source layer over epitaxial source/drain features 142 and 146 and performing a rapid thermal annealing process. During the rapid anneal process, a portion of the metal source layer over the epitaxial source/drain features 142 and 146 reacts with the silicon in the epitaxial source/drain features 142 and 146 to form a silicide layer 178. Next, the unreacted portion of the metal source layer is removed. In some embodiments, silicide layer 178 is made of metal or metal alloy silicide, and the metal includes noble metals, refractory metals, rare earth metals, alloys thereof, or combinations thereof. Next, conductive material is formed in the contact openings to form the source/drain contacts 176. The conductive material may be made of materials including one or more of Ru, Mo, Co, Ni, W, Ti, Ta, Cu, Al, TiN, and TaN. Although not shown, prior to forming the source/drain contacts 176, a barrier layer (e.g., TiN, TaN, or the like) may be formed on the sidewalls of the contact openings. Next, a planarization process such as chemical mechanical polishing is performed to remove excess deposited contact material and expose the top surface of the gate electrode layer 172.

It should be understood that the semiconductor device 100 may undergo further complementary metal oxide semiconductor (CMOS) processes and/or back-end-of-line (BEOL) processes to form various features, such as transistors, contacts/vias, interconnect metal layers, dielectric layers, passivation layers, etc. The semiconductor device 100 may also include backside source/drain contacts on the backside of substrate 101 such that the sources or drains of epitaxial source/drain features 142 and 146 are connected to the backside power rail (for example, positive voltage VDD or negative voltage VSS) via the backside source/drain contacts.

As shown in FIGS. 15 and 17, the first semiconductor material 151 is formed in the source/drain regions. The first semiconductor material 151 may include doped silicon or doped silicon germanium. In some embodiments, n-type epitaxial features are formed from portions of the substrate, and first semiconductor material 151 includes silicon doped with n-type dopants, such as arsenic or phosphorus. The N-type dopant concentration is about 1×10¹⁹/cm³ to about 5×10²⁰/cm³. In some embodiments, p-type epitaxial features are formed from portions of the substrate, and the first semiconductor material 151 includes silicon germanium doped with p-type dopants, such as boron. For example, the first semiconductor material 151 includes boron-doped silicon germanium, which has about 5 atomic percent to about 40 atomic percent of germanium and a dopant concentration of about 1×10¹⁹/cm³ to about 8×10²⁰/cm³. The first semiconductor material 151 may first be formed on the semiconductor surface by epitaxy, such as on the top surface of the substrate 101 and the lowest first semiconductor layer 106. A subsequent etching process is performed to remove a portion of the first semiconductor material 151 formed on the first semiconductor layer 106. Due to the etching process, the first semiconductor material 151 may form a concave top surface. In some embodiments, the thickness of the first semiconductor material 151 along the Z direction ranges from about 5 nm to about 50 nm.

As shown in FIGS. 15 and 17, the second semiconductor material 152 is formed on the first semiconductor layers 106 and the dielectric spacers 144. The second semiconductor material 152 may be formed by chemical vapor deposition, such as remote plasma chemical vapor deposition (RPCVD). The second semiconductor material 152 may include silicon doped with n-type dopants for n-type epitaxial features or silicon germanium doped with p-type dopants for p-type epitaxial features. For example, the second semiconductor material 152 may be silicon germanium doped with dopants, and the second semiconductor material 152 has about 25 atomic percent to about 45 atomic percent of germanium. In some embodiments, the second semiconductor material 152 has a higher atomic percentage of germanium than the first semiconductor material 151. In some embodiments, the dopant concentration of the second semiconductor material 152 may be about 1×10²⁰/cm³ to about 8×10²⁰/cm³. In some embodiments, the second semiconductor material 152 has a higher dopant concentration than the first semiconductor material 151.

The third semiconductor material 153 is formed on the second semiconductor material 152. The third semiconductor material 153 may be formed by epitaxy. The third semiconductor material 153 may include silicon doped with n-type dopants for n-type epitaxial features or silicon germanium doped with p-type dopants for p-type epitaxial features. For example, the third semiconductor material 153 may be silicon germanium doped with dopants, and the third semiconductor material 153 has about 40 atomic percent to about 60 atomic percent of germanium. In some embodiments, third semiconductor material 153 has a higher atomic percentage of germanium than second semiconductor material 152. In some embodiments, the dopant concentration of the third semiconductor material 153 may be about 5×10²⁰/cm³ to about 4×10²¹/cm³. In some embodiments, third semiconductor material 153 has a higher dopant concentration than second semiconductor material 152. An etch-back process may be performed on the third semiconductor material 153 so that the top surface of the third semiconductor material 153 is substantially the same height as the top surface of the top first semiconductor layer 106. In some embodiments, the width of the source/drain epitaxial features 142 along the X-direction is from about 10 nm to about 50 nm.

Referring to FIGS. 15 and 17, the depth H1 and width W1 of the shallow trench 118 in FIG. 15 are less than the depth H2 and width W2 of the deep trench 118′ in FIG. 17, respectively. The more the depth H2 of the deep trench 118′ is, for example, H2 is greater than 10 nm, the more difficult it is to remove the dielectric layer remaining in the deep trench 118′. The less the depth H1 of the shallow trench 118 is, for example, H1 is less than 10 nm, the easier it is to remove the dielectric layer remaining in the shallow trench 118. In addition, the wider the width W2 of the deep trench 118′ is, for example, W2 is greater than 15 nm, the more difficult it is to reduce the contact poly pitch. Therefore, less semiconductor devices 100′ can be accommodated in the same substrate area, so the density of the semiconductor device 100′ cannot be increased. The narrower the width W1 of the shallow trench 118 is, for example, W1 is less than 15 nm, the easier it is to reduce the contact poly pitch. Therefore, more semiconductor devices 100 can be accommodated in the same substrate area, so the density of the semiconductor devices 100 can be increased. In one embodiment, the depth H1 of the shallow trench 118 may be less than the Y-cut nanosheet width Wn1 of the first semiconductor layer 106 in FIG. 16 or the Y-cut nanosheet width Wn2 of the first semiconductor layer 106 in FIG. 18.

Referring to FIG. 16 and FIG. 18, the Y-cut nanosheet width Wn1 in FIG. 16 is less than the Y-cut nanosheet width Wn2 in FIG. 18. When the Y-cut nanosheet width Wn2 is longer, for example, Wn2 is greater than 12 nm, it is not conducive to reducing the epitaxial volume. Therefore, less semiconductor devices 100′ can be accommodated in the same substrate area, so the density of the semiconductor devices 100′ cannot be increased. When the Y-cut nanosheet width Wn1 is shorter, for example, Wn1 is less than 12 nm, it is beneficial to reduce the epitaxial volume. Therefore, more semiconductor devices 100 can be accommodated in the same substrate area, so the density of the semiconductor devices 100 can be increased. The semiconductor device 100 with smaller Y-cut nanosheet width and smaller contact poly pitch (CPP) in FIGS. 15 and 16 can combine with the semiconductor device 100′ with normal Y-cut nanosheet width and normal contact poly pitch (CPP) in FIGS. 17 and 18 on the same substrate 101.

The present disclosure is directed to a semiconductor device and a manufacturing method thereof for improving the depth and width of the shallow trench so as to manufacture a semiconductor device with a smaller Y-cut nanosheet width and a smaller contact poly pitch (CPP), thereby increasing the density of the semiconductor device. In addition, the manufacturing method of the semiconductor device in the present disclosure can also combine the semiconductor device with smaller Y-cut nanosheet width and smaller contact poly pitch (CPP) with the semiconductor device with normal Y-cut nanosheet width and normal contact poly pitch (CPP) on the same substrate to improve the compatibility of the semiconductor process.

According to one aspect of the present disclosure, a method for manufacturing a semiconductor device includes the following steps. A fin structure is formed on a substrate, and the fin structure includes a plurality of first semiconductor layers and a plurality of second semiconductor layers alternately stacked. A sacrificial gate structure is formed over a portion of the fin structure. The first semiconductor layers and the second semiconductor layers not covered by the sacrificial gate structure in a source/drain region of the fin structure are removed. The second semiconductor layers are removed to form at least one cavity between the first semiconductor layers. A sacrificial dielectric layer is formed between the first semiconductor layers. Edge portions and bottom portions of the sacrificial dielectric layer are removed. Dielectric spacers are formed on sidewalls of the sacrificial dielectric layer and between the first semiconductor layers. A surface of the substrate exposed in the source/drain region is etched to form a shallow trench, wherein the depth of the shallow trench is smaller than the width of the shallow trench.

According to one aspect of the present disclosure, a method for manufacturing a semiconductor device includes the following steps. A sacrificial dielectric layer is formed between a plurality of first semiconductor layers and in a source/drain region. Edge portions and bottom portions of the sacrificial dielectric layer are removed. Dielectric spacers are formed on sidewalls of the sacrificial dielectric layer and between the first semiconductor layers. A substrate surface at the bottom of the source/drain region is etched to form a shallow trench, wherein the shallow trench is formed after forming the dielectric spacers, and the depth of the shallow trench is less than the width of the shallow trench.

According to one aspect of the present disclosure, a semiconductor device including a substrate, a first epitaxial source/drain feature, a second epitaxial source/drain feature, two or more semiconductor layers and at least one dielectric spacer is provided. The substrate has a shallow trench and a separation layer filled in the shallow trench, wherein the depth of the shallow trench is less than the width of the shallow trench. The first epitaxial source/drain feature is formed on the separation layer. The second epitaxial source/drain feature is formed on the separation layer, wherein a bottom side of the first and second epitaxial source/drain features near the separation layer has a taper shape whose width is smaller than a width at a top side of the first and second epitaxial source/drain features. Two or more semiconductor layers are electrically connected between the first epitaxial source/drain feature and the second epitaxial source/drain feature. At least one dielectric spacer is located between the two or more semiconductor layers, the dielectric spacer is located on two opposite sides of the first epitaxial source/drain feature and the second epitaxial source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a fin structure on a substrate, the fin structure comprising a plurality of first semiconductor layers and a plurality of second semiconductor layers alternately stacked;
forming a sacrificial gate structure over a portion of the fin structure;
removing the first semiconductor layers and the second semiconductor layers not covered by the sacrificial gate structure in a source/drain region of the fin structure;
removing the second semiconductor layers to form at least one cavity between the first semiconductor layers;
forming a sacrificial dielectric layer between the first semiconductor layers and in the source/drain region;
removing edge portions and a bottom portion of the sacrificial dielectric layer;
forming a plurality of dielectric spacers on sidewalls of the sacrificial dielectric layer and between the first semiconductor layers; and
etching a substrate surface at the bottom of the source/drain region to form a shallow trench, wherein a depth of the shallow trench is less than a width of the shallow trench.

2. The method of claim 1, further comprising depositing a separation layer in the shallow trench.

3. The method of claim 2, further comprising forming an epitaxial source/drain feature on the separation layer.

4. The method of claim 3, further comprising:
removing the sacrificial dielectric layer between the first semiconductor layers to form a cavity;
forming a gate dielectric layer to surround the exposed surface of each of the first semiconductor layers; and
forming a gate electrode layer on the gate dielectric layer.

5. The method of claim 4, wherein the depth of the shallow trench is less than a channel width of the gate dielectric layer.

6. The method of claim 1, wherein the shallow trench is formed in the substrate after forming the dielectric spacers.

7. The method of claim 1, wherein the depth of the shallow trench is less than 10 nanometers.

8. The method of claim 1, wherein the width of the shallow trench is less than 15 nanometers.

9. A method of manufacturing a semiconductor device, comprising:
forming a sacrificial dielectric layer between a plurality of first semiconductor layers and in a source/drain region;
removing edge portions and a bottom portion of the sacrificial dielectric layer;
forming a plurality of dielectric spacers on sidewalls of the sacrificial dielectric layer and between the first semiconductor layers; and
etching a substrate surface at the bottom of the source/drain region to form a shallow trench, wherein the shallow trench is formed after forming the dielectric spacers, and a depth of the shallow trench is less than a width of the shallow trench.

10. The method of claim 9, further comprising depositing a separation layer in the shallow trench.

11. The method of claim 10, further comprising forming an epitaxial source/drain feature on the separation layer.

12. The method of claim 11, further comprising:
removing the sacrificial dielectric layer between the first semiconductor layers to form a cavity;
forming a gate dielectric layer to surround exposed surfaces of each of the first semiconductor layers; and
forming a gate electrode layer on the gate dielectric layer.

13. The method of claim 12, wherein the depth of the shallow trench is less than a nanosheet width of the first semiconductor layer.

14. The method of claim 9, wherein the depth of the shallow trench is less than 10 nanometers.

15. The method of claim 9, wherein the width of the shallow trench is less than 15 nanometers.

16. A semiconductor device, comprising:
a substrate having a shallow trench and a separation layer filled in the shallow trench, wherein a depth of the shallow trench is less than a width of the shallow trench;
a first epitaxial source/drain feature formed on the separation layer;
a second epitaxial source/drain feature formed on the separation layer, wherein a bottom side of the first and second epitaxial source/drain features near the separation layer has a taper shape whose width is smaller than a width at a top side of the first and second epitaxial source/drain features;
two or more semiconductor layers electrically connected between the first epitaxial source/drain feature and the second epitaxial source/drain feature; and
at least one dielectric spacer located between the two or more semiconductor layers, the dielectric spacer is located on two opposite sides of the first epitaxial source/drain feature and the second epitaxial source/drain feature.

17. The semiconductor device of claim 16, further comprising a gate dielectric layer surrounding each of the two or more semiconductor layers.

18. The semiconductor device of claim 17, further comprising at least one gate electrode layer located between the two or more semiconductor layers, and the gate dielectric layer surrounds the gate electrode layer.

19. The semiconductor device of claim 17, wherein a depth of the shallow trench is less than a nanosheet width of the semiconductor layer.

20. The semiconductor device of claim 17, wherein the depth of the shallow trench is less than 10 nanometers, and the width of the trench is less than 15 nanometers.
